(19) United States
(12) Patent Application Publication
(10) Pub. No.: US 2007/0188178 A1
(43) Pub. Date: Aug. 16, 2007

(54) Apparatus and method for sensing objects proximate to fluid flows

(76) Inventors: Paul H. Dietz, Hopkinton, MA (US); Jonathan Westhues, Cambridge, MA (US); Darren L. Leigh, Somerville, MA (US)

Correspondence Address: MITSUBISHI ELECTRIC RESEARCH LABORATORIES, INC., 201 BROADWAY, 8TH FLOOR, CAMBRIDGE, MA, 02139, US

(21) Appl. No.: 11/352,022

(22) Filed: Feb. 10, 2006

(51) Int. Cl. G01R 27/26

(52) U.S. Cl. 324/661

(57) ABSTRACT

An apparatus senses an object proximate to a laminar fluid flow by using the fluid as part of the sensing system. For more distant objects, an electrical system detects the capacitance between the proximate object and the flowing fluid via an impedance measurement. For objects touching the flow, an optical system detects the loss of total internal reflection. Together, the two systems allow the proximity to be determined over a wide range. A fluid flow is produced through a nozzle. An electrode is placed in the fluid. A complex impedance is measured between the electrode and an object due to capacitive coupling between the object and the fluid flow. The complex impedance is inversely proportional to a distance between the object and the fluid flow and proportional to an area of proximity of the object.

### FIELD OF THE INVENTION

This invention relates generally to sensing objects, and more particularly to sensing objects proximate to fluid flows.

### BACKGROUND OF THE INVENTION

Laminar fluid flow occurs when velocity and pressure characteristics of a fluid are substantially constant over time. A useful consequence of this property is that electro-optical characteristics of the fluid are also relatively constant. Laminar flow is easy to recognize in practice by its smooth flowing appearance.

In many applications, it is desired to determine the proximity and/or contact of an object to a fluid flow. Examples include various coating processes. Many types of sensors can be used to determine the relative positions of the fluid and the object, and thus their relative spacing.

There are many known methods for determining proximity and/or contact to a static fluid. For example, the Dwyer Model 1430, Microtector Electronic Point Gage, manufactured by Dwyer Instruments, Inc., Michigan City, Ind., U.S.A., determines fluid contact with a test probe by measuring the electrical resistance between the probe and the fluid.

U.S. Pat. No. 5,730,165, “Time domain capacitive field detector,” issued to Philipp on Mar. 24, 1998, describes a system and method of sensing the proximity of a hand to a faucet, and continued presence of a hand in the flowing water via a capacitance measurement. However, that system does not measure the relative proximity of an object to the flowing fluid, in a general sense. The system yields a binary response—either the hand is in the fluid flow or not. That system cannot determine a degree of proximity to the fluid flow, or a degree of insertion into the fluid flow.

It is also known in the art that laminar fluid flows can transmit light via internal reflection. A common physics demonstration is to shine a laser beam through water in a container with a drain hole on an opposite side. The light follows the curving fluid flow until the fluid flow breaks apart. This effect is used in fountains to create aesthetically pleasing displays.

It is desired to accurately measure a relative position of a laminar fluid flow with respect to an object.

### SUMMARY OF THE INVENTION

Laminar flow allows a fluid to have substantially constant electro-optical characteristics over time. The embodiments of the present invention use the fluid flow as a sensing element in a sensor system. The laminar fluid flow is produced by an appropriately shaped nozzle. A light source is suitably arranged, e.g., in the nozzle, so as to allow light to travel through the fluid flow via total internal reflection. Essentially, the fluid serves as a light pipe. This requires the fluid to be substantially transparent to the wavelength of the light used.

When an object approaches the flow, the object changes the optical characteristics of the fluid ‘light pipe’. This change can be detected with optical sensors in three distinct ways.

First, a sensor can be placed on the other side of the detection area to measure the intensity of the light traveling through the fluid. Second, a sensor can be placed near the light source and arranged to detect a change in reflectance. Third, a sensor can be placed so as to detect light escaping from the fluid in a detection area. Examples of appropriate light sensors include photodiodes, photoresistors, and cameras.

This optical technique only detects objects touching the fluid flow, or objects in extreme close proximity to the fluid flow.

In order to extend the sensing range, the fluid flow is used as an electrode in a capacitive proximity sensing apparatus. This requires the fluid, e.g., water, to be somewhat electrically conductive.

Laminar flow ensures a consistent physical shape of the fluid, and also maintains electrical continuity. Thus, an electrical contact placed in the flowing stream provides an electrical connection to the entire stream. Any sufficiently conductive object that is placed near the stream will effectively form a capacitor with the fluid serving as one electrode, and the object as the other. The magnitude of this capacitive coupling will be roughly proportional to the area of the proximate surfaces and inversely proportional to the distance between them.

In one embodiment of the invention, the object is electrically connected to ground via a sufficiently small impedance and thus the capacitance of the fluid to ground increases as the distance between the fluid and the object decreases. In many circumstances, the proximity of the object to grounded surfaces provides adequate capacitive coupling and hence, low impedance, without additional connections. The result is that one can measure the impedance between the fluid contact and ground, and this will change depending upon the placement of the object with respect to the flowing fluid.

The impedance between a contact in the fluid stream and the object will include a resistive component due to the resistivity of the fluid. This component will vary depending upon how far down the stream the proximate object is positioned. By looking at both the resistive and reactive components of the impedance, both the distance between the object and the fluid flow, and the positioning of the object along the fluid flow can be determined.

Because the flowing fluid is resistive, the impedance measurement includes a resistive component that is indicative of the position along the flowing stream of the proximate object with respect to the point of electrical contact.

The electrical and optical sensing modes are independent and can be used singularly, or in combination at any time. Because the two techniques work best at different distances, using both concurrently enables a greater working range.

Furthermore, it is possible to detect where the object is along the fluid flow, that is, the distance from the nozzle to the object measured along the fluid flow.

### BRIEF DESCRIPTION OF THE DRAWINGS

FIG. 1 is a side view of an apparatus for measuring a distance between an object and a fluid flow according to an embodiment of the invention;

FIG. 2 is a side view of a fountain according to an embodiment of the invention;

FIG. 3 is a side view of a water harp according to an embodiment of the invention; and

FIG. 4 is a side view of a bidet according to an embodiment of the invention.

### DETAILED DESCRIPTION OF THE PREFERRED EMBODIMENT

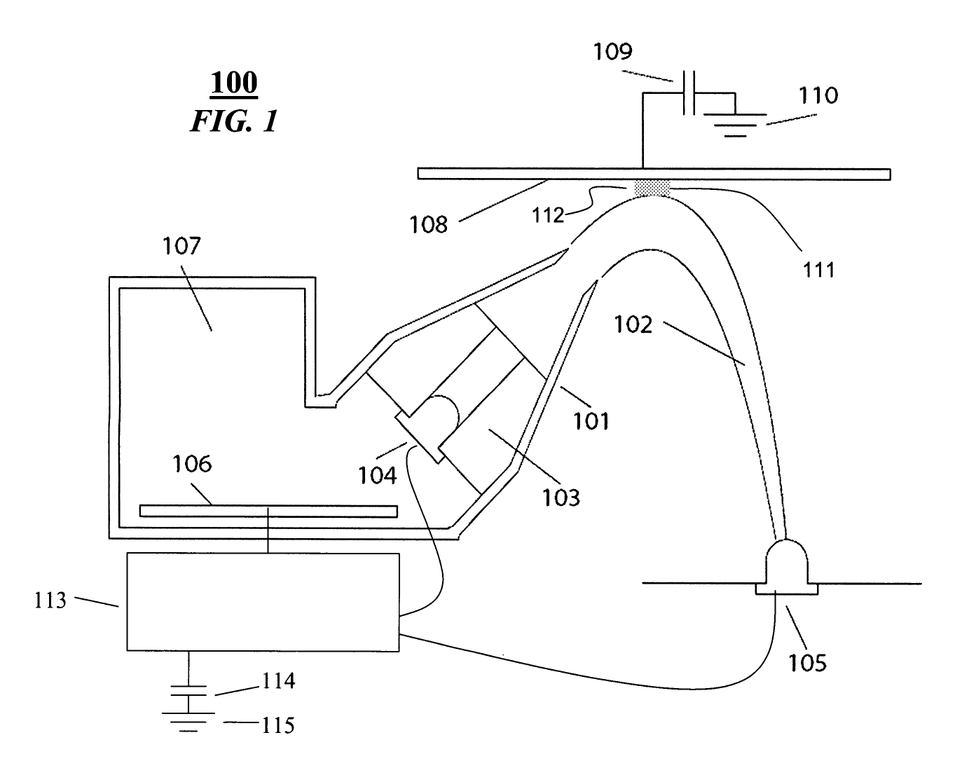

FIG. 1 shows an apparatus 100 for measuring a proximity of an object 108 to a fluid flow 102 according to one embodiment of the invention. That is, the apparatus measures the width of an air gap 111 between the object 108 and the fluid flow 102. A nozzle 101 produces the flow of the fluid 102 having a laminar flow. The fluid is obtained from a suitable fluid source 107. It should be noted, that the flow does not need to be perfectly laminar. Any flow that is sufficiently uniform over time to maintain substantially constant electrical and optical characteristics suffices.

Two mechanisms, one electrical and the other optical, are used to accommodate measuring a large range of distances. A light source 104 is suitably arranged to allow light to travel through the fluid flow 102, due to internal reflection. Hence, the fluid flow serves as an optical waveguide. The light source 104 is held in place by flow straightening fins 103 so that the light source does not impede laminar flow from the nozzle 101.

An optical sensor 105 measures, via controller 113, an intensity of light that passes through the fluid flow 102. As the object 108 approaches and then touches the fluid flow 102, the internal reflection is compromised and light escapes in the region of contact. This decreases the intensity of the light at the optical sensor 105. The location of the optical source 104 and the optical sensor can be reversed without changing the functionality of the apparatus.

The optical sensor can be placed near the point of contact between the fluid and the object to detect the escaped light, or adjacent to the light source 104 to detect light reflected by the object and traveling back ‘upstream’. Alternatively, multiple optical sensors can be placed at various positions relative to the fluid flow, such as near the nozzle, near the point of contact, and near the end of the fluid flow.

Unfortunately, the optical system is only useful for detecting extremely close proximity of the object, that is, within the near field of the waveguide, or actual contact. To increase the range, an electrical system is utilized. An electrode 106 provides an electrical connection to the fluid source 107. The electrode is connected to a controller 113, an electronic circuit capable of measuring capacitance or, more generally, complex impedance from the electrode to the object, via some electrical path. In FIG. 1, the connection between the controller 113 and the object 108 is shown schematically as capacitors 114 and 109 which both connect to each other via ground connections 115 and 110, respectively. In other embodiments, the connection can take other forms so long as the impedance between the controller and the object is sufficiently small. In this embodiment, capacitors 109 and 114 represent a point that is electrically connected to the object. Typically, this other point is the circuit ground 110. In FIG. 1, the capacitance 109 of the object 108 to ground 110 comprises the electrical connection to ground and is shown schematically. This represents the inherent capacitance due to proximity to ground rather than an additional component of the system.

Due to the nature of laminar flow, the fluid in the source 107 is continuously connected to the fluid flow 102 exiting the nozzle 101. It is presumed that the fluid, e.g., water, is at least moderately conductive, and thus provides an electrical connection between the electrode 106 and the fluid flow 102, having a relatively constant impedance over time. It should be noted that the electrode, e.g., a small diameter copper wire, can also be placed directly in the fluid flow 102, for example, at the nozzle 101. Any conductor in contact with the fluid could suffice.

The object 108, e.g., a hand, is also at least moderately conductive. The object is either directly or capacitively coupled to the controller 113 via some electrical path to ground. In FIG. 1, this is shown schematically as capacitors 114 and 109, which are connected via ground connections 115, and 110.

The air gap 111 between the object 108 and the fluid flow 102 forms a capacitor 112. The capacitor can be measured by the controller 113 via a change in the reactive component of the complex impedance between the electrode 106 and its connection to ground 115. The resistive component of the impedance is typically dominated by the resistance of the fluid between the electrode and the area in proximity to the object. This can be used to determine the approximate location of the proximal object 108 along the stream 102.

In many instances, it is desirable to isolate different fluid regions so that the different fluid regions can have independent sensing. For the optical technique, this can be accomplished by having sufficiently sharp turns in the fluid flow, breaking the light path. For the electrical technique, isolation can be achieved by having sufficiently long and narrow connections to yield a high impedance. Thus, the proximity of the object 108 to the fluid flow 102 can be measured at a distance. In addition, the resistive component of the complex impedance can be used to determine the approximate location along the stream of the additional capacitance 109 associated with the proximal object 108.

The measurements can also indicate approximately at which point along the fluid flow the object is positioned, i.e., the distance, along the flow fluid, from the object to the nozzle. It should be noted that the distance is not necessarily a straight line distance, but rather a distance that follows the flow.

While the two measurement techniques can be used together to cover a broad range of distances, either technique can be used by itself when only a limited range is required.

Applications

There are numerous applications for the embodiments of the invention in process control, where the distance between a fluid flow and an object must be sensed and maintained precisely.

It is also possible to use the invention to measure the distance between two fluids. In this case, the object 108 is also a fluid.

A particularly novel application of the invention concerns interactive water displays. Water is both sufficiently transparent and sufficiently conductive to allow for both optical and electrical measurements as described above. This allows laminar flowing water displays to react to proximity and/or touch by a person.

Typically, a person standing directly or indirectly on the ‘ground’ has a capacitance to ground of about 100 pF. Thus, no additional electrical connection between the person and ground is required to enable capacitive sensing.

In one embodiment, the fluid flow is shaped into a ‘water bell,’ a common term in fountain design, via an appropriately shaped deflector. The pump speed is varied depending upon a measured capacitance, which indicates hand proximity. The system attempts to keep the water at a constant minimum distance from the person's hand. This creates the illusion that a person can sculpt the water bell by bringing a hand near the flowing water.

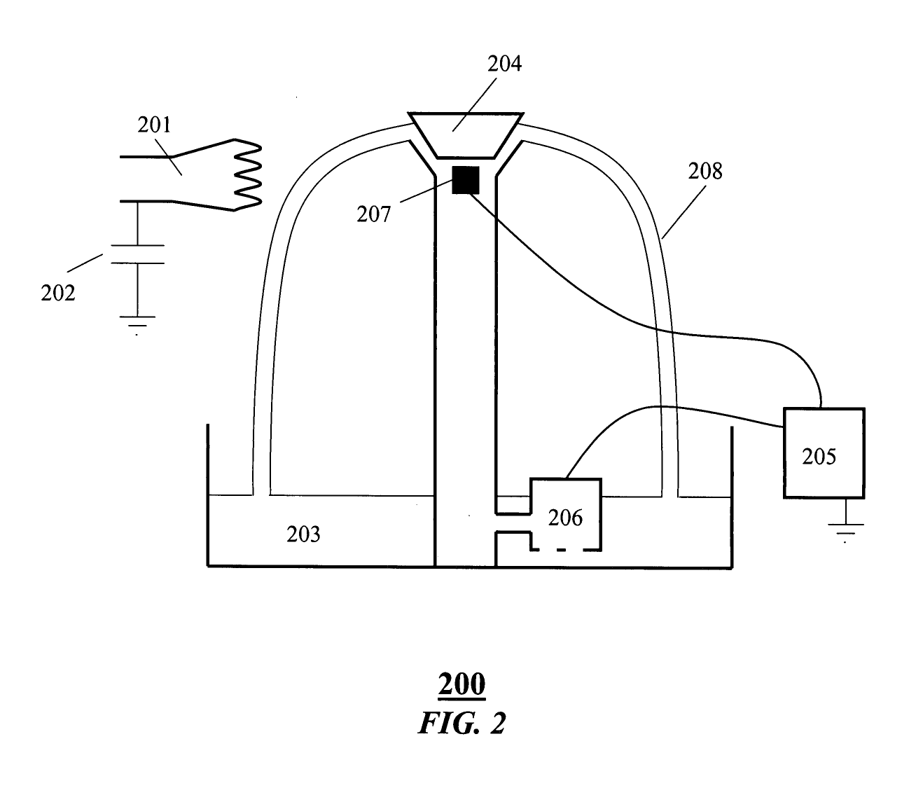

This embodiment can be understood with the aid of FIG. 2. Fountain 200 uses water 203 which is pumped upward via pump 206. When the water hits deflector 204, it is shaped into a water bell 208. The fountain uses this laminar flowing water 208 as an electrode to measure capacitance to ground. The capacitance of the person to ground is shown schematically on FIG. 2 as capacitor 202. A grounded controller 205 is connected to the fluid 208 via an immersed electrode 207. When a person approaches the fluid flow in the fountain 208, for example, by reaching out and attempting to touch the water with a hand 201, the capacitance increases, and the controller 205 detects this change and decreases pump speed of pump 206. The overall effect is that the water flow in the fountain 200 withdraws from an attempted touch. Similarly, if the hand is withdrawn, the capacitance will decrease, and the controller 205 then increases the pump speed allowing the water bell to increase in size. Thus, the water bell grows and shrinks in accordance with hand gestures. Other interactive programs can easily be added to the controller 205. For example, the fountain 200 can be programmed to withdraw only up to a point. When that point is reached, the pump speed is rapidly increased, purposely wetting the user's hand 201.

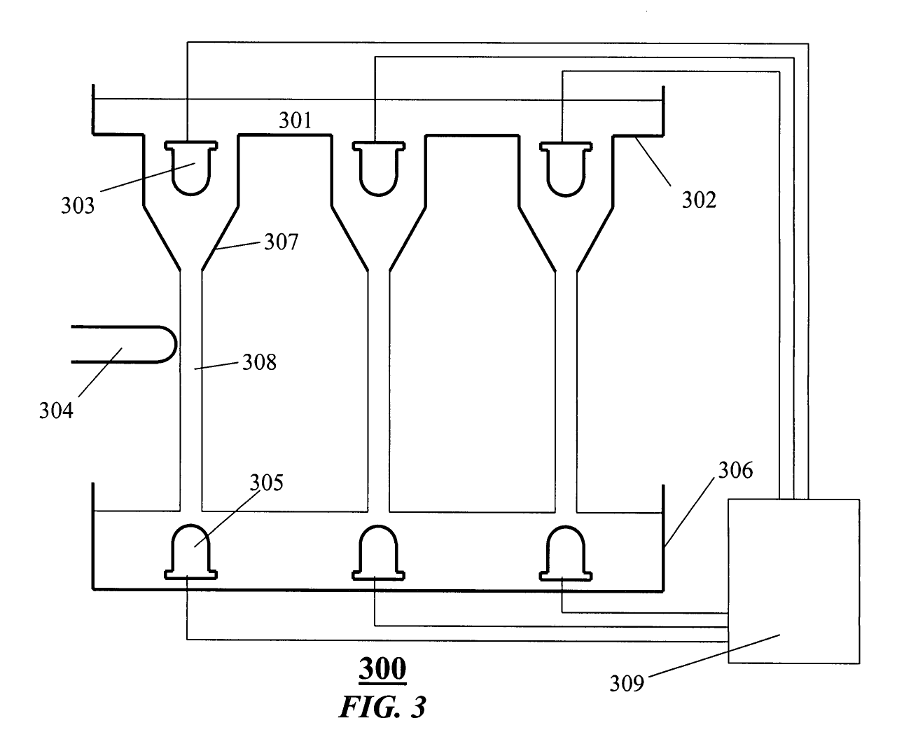

A second example of an interactive display is a ‘water harp’ 300 where the strings are made of laminar flowing water as shown in FIG. 3. Water 301 in a reservoir 302 flows out of a plurality of nozzles 307, forming laminar streams 308. Each nozzle 307 incorporates a light emitting device 303 which allows light to be transmitted down the stream 308 via total internal reflection. Light detectors 305 are positioned a in receiving reservoir 306 so as to detect the light. A controller 309 is connected to the light emitters 303 and detectors 305. When a finger 304 contacts the stream, the total internal reflection is partially broken, and light escapes. This causes the light reaching detector 305 to decrease. Controller 309 notes this change and triggers a musical sound. The escaping light provides a pleasing visual effect. A pump, not shown in the figure, maintains the water levels in the reservoirs. Playing the harp is a unique experience due to the tactile feedback of touching a water stream, and the visual appearance of the escaping light as each note is played and heard.

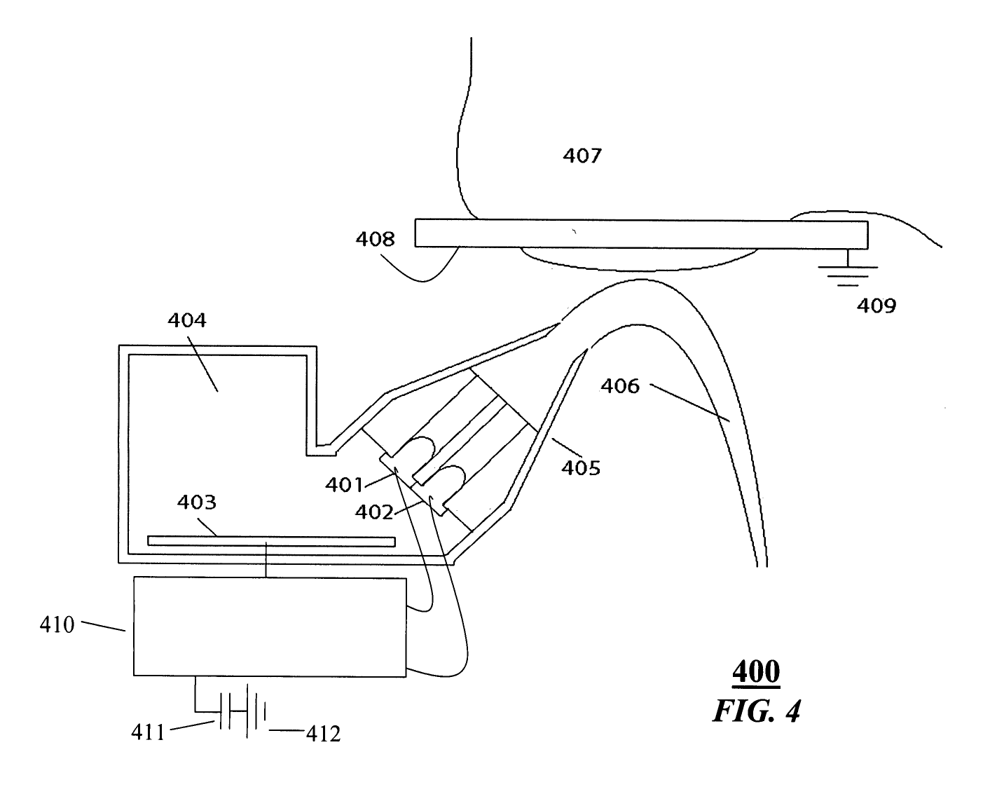

FIG. 4 shows another novel application of the invention in the area of personal hygiene. A bidet 400 produces a water stream 406, which provides a cleansing function. A person 407 sits on a seat 408 that is grounded, shown schematically via ground 409, and that provides a low impedance path between the seated person and ground. A water supply 404 is forced through nozzle 405 to produce the water stream 406. Electrode 403 provides an electrical contact to the stream. Light emitter 401 sends light through the stream, and light detector 402 measures the light which is reflected back through the stream. With this arrangement, the controller 410 can electrically determine the proximity of a person to the stream via an impedance measurement, allowing the flow to be suitably adjusted. The connection between the controller 410 and the person 407 should be of sufficiently low impedance, and is represented schematically on the figure as capacitor 411 and ground connections 412 and 409. The reflectance of light off the area being cleansed can give an indication of the current state of cleanliness, and this can be used to adjust timing and flow rate.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. An apparatus for sensing an object proximate to a fluid flow, comprising:
means for producing a fluid flow;
an electrode placed in the fluid;
means for measuring an electrically complex impedance between the electrode and an object via an electrical connection due to a capacitive coupling between the object and the fluid flow, the complex impedance being dependent upon the relative positions of the object and the fluid flow, being inversely proportional to a distance between the object and the fluid flow, and being proportional to an area of proximity of the object to the fluid flow.

2. The apparatus of claim 1, in which the fluid flow is substantially laminar.

3. The apparatus of claim 1, in which the fluid flow is sufficiently uniform over time to maintain substantially constant electrical and optical characteristics.

4. The apparatus of claim 1, further comprising:
a light source configured to emit light into the fluid flow such that the light may travel inside the fluid flow via internal reflection; and
an optical detector placed in the fluid flow, in which the optical detector is configured to measure an intensity of light transmitted through the fluid flow.

5. The apparatus of claim 4, in which the optical detector is placed in the fluid flow to measure an intensity of reflected light.

6. The apparatus of claim 4, in which the optical detector is placed outside the fluid flow to measure an intensity of light escaping from the fluid flow.

7. The apparatus of claim 1, further comprising:
means for measuring a capacitance between the fluid flow and the object.

8. The apparatus of claim 1, further comprising:
means for breaking the fluid flow into different regions; and
measuring the complex impedance in each of the different regions.

9. The apparatus of claim 7, further comprising:
means for controlling a rate of fluid flow in response to the measuring of the complex impedance.

10. The apparatus of claim 7, further comprising:
a light source emitting light into the fluid flow; and
means for generating an acoustic signal in response to measuring the complex impedance.

11. The apparatus of claim 10, further comprising;
means for producing a plurality of fluid flows;
an electrode placed in each fluid;
means for measuring the complex impedance between each electrode and the object via an electrical connection due to a capacitive coupling between the object and the fluid flows, a capacitive component of the complex impedance being dependent upon a relative position of the object and the fluid flow, being approximately inversely proportional to a distance between the object and the fluid flow, and being proportional to an area of proximity of the object to the fluid flow; and
means for generating acoustic signals in response to the measuring.

12. The apparatus of claim 11, in which the acoustic signals correspond to tones on a musical scale.

13. The apparatus of claim 1, in which the apparatus is arranged in a bidet, and the object is a person.

14. The apparatus of claim 1, in which the means for producing the fluid flow includes a nozzle, and the electrically complex impedance is inversely proportional to a distance from the nozzle to the object along the fluid flow.

15. The apparatus of claim 4, in which the means for producing the fluid flow includes a nozzle, and the intensity is inversely proportional to a distance from the nozzle to the object along the fluid flow.

17. An apparatus for sensing an object proximate to a fluid flow, comprising:
means for producing a fluid flow;
a light source placed in the fluid;
means for measuring an intensity of light in the fluid flow, the intensity being inversely proportional to a distance between the object and fluid flow and proportional to an area of proximity of the object.

18. A method for sensing an object proximate to a fluid flow, comprising:
producing a fluid flow;
means for measuring the electrical complex impedance between an electrode and an object via an electrical connection due to a capacitive coupling between the object and the fluid flow, the complex impedance being dependent upon the relative positions of the object and the fluid flow, being inversely proportional to a distance between the object and the fluid flow, and being proportional to an area of proximity of the object to the fluid flow.
